(19) United States
(12) Patent Application Publication
(10) Pub. No.: US 2025/0269394 A1
(43) Pub. Date: Aug. 28, 2025

(54) POSITIONING DEVICE HAVING RAM PRESSURE NOZZLES AND A METHOD OF ALIGNING A SUBSTRATE

(71) Applicant: SUSS MicroTec Solutions GmbH & Co. KG, Sternenfels (DE)

(72) Inventor: Sven HANSEN, Sternenfels (DE)

(21) Appl. No.: 19/061,710

(22) Filed: Feb. 24, 2025

(30) Foreign Application Priority Data
Feb. 22, 2024 (NL) 2037102

(51) Int. Cl. B05B 13/02; B05B 12/08

(52) U.S. Cl. CPC B05B 13/0221; B05B 12/085

(57) ABSTRACT

A positioning device for aligning a substrate relative to a substantially flat surface includes a substrate receiving device configured for receiving the substrate and at least three ram pressure nozzles arranged on or around the substrate receiving device. Each of the ram pressure nozzles is oriented towards the substantially flat surface and is connected to a pressure measuring device for sensing the respective ram pressure thereof. At least two linear actuators connected to the substrate receiving device are provided, the actuators being configured to move the substrate receiving device relative to the substantially flat surface. A control unit is provided which is configured to preset travel paths of the linear actuators as a function of the measured ram pressures.

The present invention relates to a positioning device and to a method of aligning a substrate relative to a substantially flat surface.

### BACKGROUND OF THE INVENTION

For the manufacture of micro- and/or nanostructured components, it is often necessary to precisely align components relative to each other, for example a substrate relative to a mask.

The mask and the substrate can either lie flat against each other or preferably be positioned parallel to each other with a small gap width, for example of 20 μm. To achieve this, wedge error compensation heads are typically used. If there is a contact between the mask and the substrate, wedge error compensation is often purely mechanical. The substrate is pressed against the mask. The wedge error compensation head aligns the substrate or a substrate holder parallel to the mask as a result of the pressure. This parallel position is then fixed by brakes.

However, this solution implies a number of problems. The mechanics in conventional wedge error compensation heads are technically complicated and accordingly expensive to manufacture. In addition, sensitive substrates can be damaged by the contact pressure.

There are also active wedge error compensation heads in which, for example, piezoelectric actuators are used to align a substrate with respect to a mask. However, the integration of the actuators in such wedge error compensation heads is complicated and therefore not easy to implement.

It is therefore the object of the invention to provide a method and a system enabling a technically simple and reliable positioning of a substrate relative to a substantially flat component.

### BRIEF DESCRIPTION OF THE INVENTION

According to the invention, this object is achieved by a positioning device for aligning a substrate relative to a substantially flat surface. The positioning device comprises:
a substrate receiving device for receiving the substrate;
at least three ram pressure nozzles arranged on or around the substrate receiving device, each of the ram pressure nozzles being oriented towards the substantially flat surface and being connected to a pressure measuring device for sensing the respective ram pressure thereof;
at least two linear actuators connected to the substrate receiving device and each configured to move the substrate receiving device relative to the substantially flat surface; and
a control unit which is configured and set up to preset travel paths of the linear actuators as a function of the measured ram pressures.

The basic idea of the invention is to sense ram pressures at various points on or around the substrate receiving device by means of the positioning device and thus obtain local distance information of the substrate or the substrate receiving device from the substantially flat surface. The substantially flat surface can, for example, be the surface of a mask or a stamp. Based on the information obtained, a contactless wedge error compensation can then be realized.

In the context of the present application, a substantially flat surface is understood to be a surface which may have unevenness, for example in the nano, micro, millimeter and/or centimeter range.

The wedge error compensation can thus be carried out particularly quickly and without damaging the substrate. In addition, the positioning device according to the invention also enables wedge error compensation to be carried out for substrates having different thicknesses, thickness variations and/or structuring. The thickness of the substrates may be preset and/or be determined in advance on a measuring stand, e.g. by means of a so-called aligner. Tilting movements and/or tolerances of the substrate holder and the mask can also be taken into account and compensated for.

In one embodiment, it is provided that the positioning device further comprises a support. The linear actuators are arranged spaced apart from each other on the support. This makes it possible for the substrate receiving device to be aligned or adjusted relative to the support.

If there is an odd number of linear actuators, the linear actuators can be evenly spaced apart from each other.

Optionally, the support is part of a lifting device. By moving the support by means of the lifting device, a time-saving rough adjustment can be made before the substrate is precisely aligned with respect to the substantially flat surface by means of the linear actuators.

In particular, the support is a support plate and/or the substrate receiving device is a substrate receiving plate.

The linear actuators may be configured as piezoelectric pins, for example.

In one variant of the invention, the linear actuators are permanently installed in the positioning device, in particular with the substrate receiving device and/or the support. This ensures that the linear actuators do not slip.

The linear actuators can be attached on the support mechanically, magnetically, by means of adhesive and/or by means of a vacuum. This is technically easy to implement. In particular, if vacuum channels are provided on the substrate receiving device for sucking in the substrate, the same vacuum system can be used to fix the linear actuators. Of course, this is not to be understood in a restrictive way. Fastening by means of screws, bolts, latching elements, adhesive connections or other connection systems is also conceivable.

It may be provided that the support and the substrate receiving device form a closed component, for example a chuck, in which at least the linear actuators are received, the substrate receiving device being adapted to be adjusted relative to the support by the linear actuators. This allows an extremely compact and space-saving design to be achieved.

For example, the support can represent at least part of the underside of the formed component and/or the substrate receiving device can represent at least part of the upper side of the formed component.

Preferably, the ram pressure nozzles are arranged outside a substrate receiving surface of the substrate receiving device, in particular evenly distributed around the latter. This prevents the measurement of the ram pressures from being disturbed by the substrate.

The operating distance of the ram pressure nozzles may be smaller than the thickness of substrates typically to be aligned.

To enable the ram pressure nozzles to work in an optimum operating range even for thicker substrates, the ram pressure nozzles may be arranged so as to protrude beyond the substrate receiving surface of the substrate receiving device in the direction of the substantially flat surface.

Alternatively, blasted geometries may however also be provided which are stationary with respect to the substantially flat surface and protrude beyond the substantially flat surface in the direction of the substrate receiving device. In the simplest case, the blasted geometries may be specially shaped areas of a mask and/or a stamp, which are blasted by the ram pressure nozzles.

The positioning device may also have a linear guide, for example a linear axis, which guides the substrate receiving device linearly during movements towards or away from the substantially flat surface. This makes it technically simple and effective to prevent the substrate receiving device from moving sideways and/or twisting.

It is also conceivable that the positioning device comprises a reference ram pressure nozzle, the ram pressure of which is substantially independent of a relative position of the substrate receiving device to the substantially flat surface and/or is dependent on an ambient pressure. For example, the reference ram pressure nozzle can eject an air flow into an environment in which there is no obstacle to the air flow at least in the vicinity of the ejection point. The ram pressure of the reference ram pressure nozzle then serves as a measure for the air pressure. Accordingly, the reference ram pressure or the air pressure can be taken into account when determining the travel paths of the linear actuators, as a result of which a particularly high positioning accuracy is achieved.

According to the invention, the object is further achieved by a method of aligning a substrate relative to a substantially flat surface by means of a positioning device according to the invention. The method comprises the steps of:
moving the substrate receiving device towards the substantially flat surface, ram pressures of the ram pressure nozzles being sensed during moving;
determining local distance values of the substrate receiving device from the substantially flat surface on the basis of the ram pressures;
determining a travel path of at least one of the linear actuators based on the local distance values; and
moving the at least one linear actuator by the travel path.

For example, the local distance values can be determined directly by means of the, in particular continuously measured, ram pressures and the distances correlating therewith.

Alternatively, the local distance values can be determined indirectly by means of ram pressure switching points and the correlating local distance values, the in particular constant movement speed of the lifting device in the direction of the substantially flat surface, the elapsed time between reaching the respective ram pressure switching point of a ram pressure nozzle and the end of the movement of the substrate receiving surface and/or the position coordinates of the ram pressure nozzles.

In particular, the step of determining a travel path of at least one of the linear actuators comprises identifying a distance by which a piezoelectric pin must be extended or retracted to achieve a parallel alignment of the substrate to the substantially flat surface at a desired distance.

Of course, different travel paths can also be determined for a plurality of different linear actuators.

The advantages discussed with respect to the positioning device apply accordingly to the method.

In one variant, the method further comprises the following step: determining a substrate dimension, in particular a substrate thickness and/or a wedge shape, the travel distance being determined based on the local distance values and the substrate dimension. The determination of a substrate dimension is carried out in particular prior to the other process steps. The process step can also be carried out outside the positioning device by means of a measuring device provided therefor.

This process step is particularly useful if different substrates are to be aligned which do not all have a uniform thickness and/or wedge shape, as this allows the dimensions of each individual substrate to be taken into account individually during alignment.

Alternatively, a known substrate dimension and/or wedge shape can be specified for a specific substrate type.

The method can also include the additional step of calibrating the pressure measuring devices by detecting and storing a correlation of a ram pressure of at least one of the ram pressure nozzles and a distance of the at least one ram pressure nozzle from the substantially flat surface. This calibration step ensures that the travel paths of the linear actuators are always calculated correctly. Calibration may also be performed depending on the air pressure. In this case, different data sets are generated and stored for different air pressures, which can be detected using the reference ram pressure nozzle, for example, and which each reflect a correlation of the ram pressure and the distance of the ram pressure nozzle from the substantially flat surface at the given air pressure.

In one variant of the method, the determination of the local distance values, the determination of the travel path and/or the movement of the at least one linear actuator by the travel path are carried out continuously while the substrate receiving device is moved towards the substantially flat surface. This constitutes a particularly efficient process sequence, which saves process time and therefore increases throughput.

Alternatively, a ram pressure switching point can be specified, wherein in the event that the ram pressure of a ram pressure nozzle reaches the ram pressure switching point, the pressure measuring device outputs a signal, wherein the determination of the local distance values and/or the determination of the travel path is initiated by the signal. By providing a ram pressure switching point, the method is technically easier to implement and less computationally complex.

In this context, it may also be provided that when the signal is output, a movement of the substrate receiving device (for example by means of the lifting device and/or by means of the linear actuators) is stopped and/or the travel path is set to zero.

Alternatively, it may be provided that the ram pressure switching points of all ram pressure nozzles are reached during the movement of the substrate receiving surface towards the substantially flat surface, in particular wherein the ram pressure switching points of at least two ram pressure nozzles do not switch substantially simultaneously but at different times if the substrate receiving surface is not aligned parallel to the substantially flat surface. By means of the ram pressure switching points and the local distance values correlating therewith, the speed of movement of the lifting device in the direction of the substantially flat surface, which is in particular constant until all ram pressure switching points are reached, the elapsed time between reaching the respective ram pressure switching point of a ram pressure nozzle and the end of the movement of the substrate receiving surface and/or the position coordinates of the ram pressure nozzles, it is possible to determine the final, i.e. the local distance values present at the end of the movement of the substrate receiving surface and consequently the travel path of at least one linear actuator.

Preferably, when determining the travel path of at least one linear actuator, the ram pressure nozzle can be used as a static reference point which is furthest away from the substantially flat surface at the time of the end of the movement of the substrate receiving surface, i.e. the ram pressure switching point of which was reached last and/or is still reached at the time of the end of the movement of the substrate receiving surface. As a result of such a determination of the travel path of at least one linear actuator, at least one linear actuator is moved such that all ram pressure nozzles which are not used as a static reference point are moved to a position at which they have their respective ram pressure switching point. If, at the time of the end of the movement of the substrate receiving surface, the ram pressure nozzle used as a static reference point had still reached its ram pressure switching point, all ram pressure nozzles have reached their ram pressure switching point after the actuators have been moved as explained above, so that the substrate receiving surface is now aligned parallel to the substantially flat surface. If, at the time of the end of the movement of the substrate receiving surface, the ram pressure nozzle used as a static reference point had not (or no longer) reached its ram pressure switching point, at least the ram pressure nozzle used as a static reference point must be moved to a position at which it has its respective ram pressure switching point, for example via the lifting device or at least one linear actuator, after or before the parallel alignment of the substrate receiving surface to the substantially flat surface. In both cases, after the parallel alignment of the substrate receiving surface to the substantially flat surface, the substrate receiving surface only needs to be moved a small distance, or even no distance at all, so that all ram pressure nozzles reach their ram pressure switching point and the desired distance between the substrate receiving surface and the substantially flat surface is thus achieved.

Alternatively, any of the ram pressure nozzles can be used as a static reference point for aligning the substrate receiving surface parallel to the substantially flat surface by means of the linear actuators. If necessary, a repeated “approach” of the substrate receiving surface to the substantially flat surface is required to achieve the desired distance between the substrate receiving surface and the substantially flat surface.

In an optional further step, it may be provided that, after the parallel alignment of the substrate receiving surface to the substantially flat surface, the substrate receiving surface is moved away from the substantially flat surface again and back towards the substantially flat surface until a switching point of at least one ram pressure nozzle is reached again. In this way, it can be checked whether the ram pressure switching points of all ram pressure nozzles are reached simultaneously within a tolerance range to be defined, and thus whether the desired parallelism of the substrate receiving surface and the substantially flat surface is provided. If the times of the ram pressure switching points are outside the tolerance range to be defined, individual steps or all previous steps can be repeated to achieve the desired parallelism of the substrate receiving surface and the substantially flat surface.

The tolerance range can extend in the millisecond range.

### BRIEF DESCRIPTION OF THE DRAWINGS

Further advantages and features of the invention will become apparent from the description below and from the accompanying drawings, to which reference is made and in which:

FIG. 1 shows a lateral view of a first embodiment of a positioning device according to the invention;

FIG. 2 shows a schematic top view of the positioning device of FIG. 1; and

FIG. 3 shows a schematic lateral view of a second embodiment of a positioning device according to the invention.

### DETAILED DESCRIPTION OF THE INVENTION

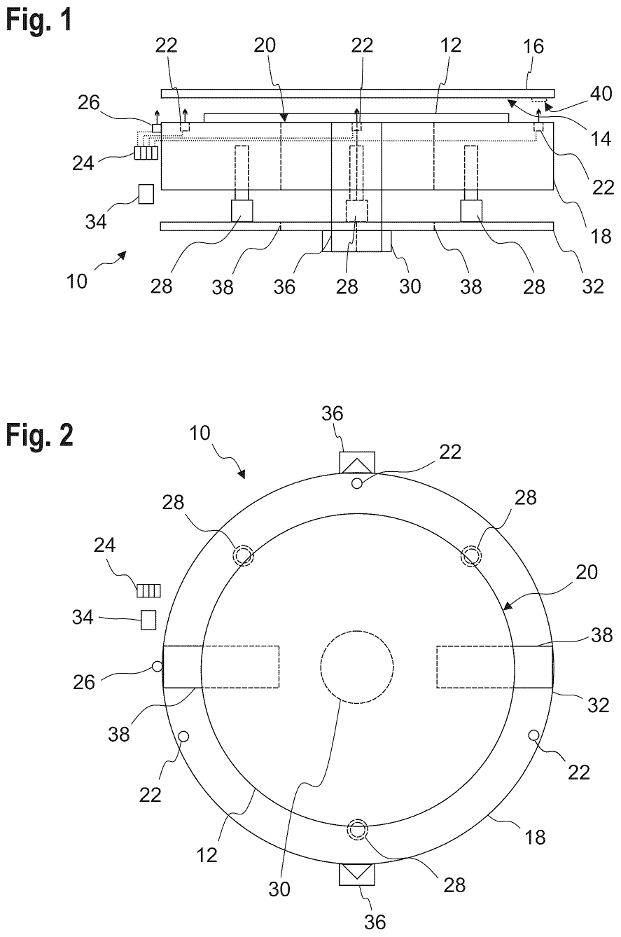

FIGS. 1 and 2 show an example embodiment of a positioning device 10 according to the invention for aligning a substrate 12 relative to a substantially flat surface 14 of a mask 16.

The positioning device 10 comprises a substrate receiving device 18 having a substrate receiving surface 20 for receiving the substrate 12.

In the example embodiment shown, the substrate receiving device 18 is a substrate receiving plate.

In an edge region of the substrate receiving device 18, three ram pressure nozzles 22 are arranged outside the substrate receiving surface 20, all of which are aligned towards the substantially flat surface 14.

In the example embodiment, the ram pressure nozzles 22 are designed for an operating range of 1 mbar to 5000 mbar and are preferably operated between 200 mbar and 2000 mbar.

Each of the ram pressure nozzles 22 is connected to a pressure measuring device 24 for sensing the respective ram pressure thereof. The closer the substrate receiving device 18 is located to the substantially flat surface 14 of the mask 16, the more an air flow generated by the respective ram pressure nozzles 22 is accumulated, which leads to an increase in pressure. This increase in pressure can be sensed by means of the pressure measuring devices 24. The measured pressure is therefore a direct and accurate measure of the distance of the substrate receiving device 18 or the ram pressure nozzles 22 from the substantially flat surface 14 and can thus be used to check and/or purposefully adjust it.

The operating distance of the ram pressure nozzles 22, i.e. the distance at which the ram pressure nozzles 22 are to be positioned in relation to a surface to be blasted for optimum function, can also be smaller than the thickness of substrates 12 typically to be aligned.

To enable operation of the ram pressure nozzles 22 in an ideal operating range, the positioning device 10 can comprise blasted geometries 40 which are arranged on or next to the mask 16 and which protrude beyond the substantially flat surface 14 in the direction of the substrate receiving device 18. In the simplest case, the blasted geometries 40 may be specially shaped regions on the edge of the mask 16 which are blasted by the ram pressure nozzles 22.

Alternatively, the ram pressure nozzles 22 can also be arranged so as to protrude beyond the substrate receiving surface 20 of the substrate receiving device 18 in the direction of the substantially flat surface 14.

Of course, ram pressure nozzles 22 which have an adjustable position are also conceivable.

In the example embodiment, the positioning device 10 also has an optional reference ram pressure nozzle 26. The reference ram pressure nozzle 26 is attached laterally to the substrate receiving device 18 and is arranged such that an air flow generated by it can exit unhindered. As a result, the ram pressure of the reference ram pressure nozzle 26 is substantially dependent on the ambient pressure and is suitable for quantifying the latter. The ambient pressure can then be taken into account accordingly when aligning the substrate 12.

In the present embodiment, the positioning device 10 furthermore comprises three linear actuators 28 which are movably connected to the substrate receiving device 18.

Alternatively, the positioning device 10 may have two, four or a plurality of actuators 28.

In the example embodiment, the linear actuators 28 are piezoelectric pins and are configured to move the substrate receiving device 18 towards or away from the substantially flat surface 14.

The positioning device 10 further comprises a support 32 on which the linear actuators 28 are evenly spaced apart from each other.

In the example embodiment shown, the support 32 is a support plate and part of a lifting device 30.

The lifting device 30 serves to be able to move the substrate receiving device 18 quickly and over longer travel paths towards or away from the mask 16.

In contrast thereto, the linear actuators 28 are used for fine adjustment. In the example embodiment, they are screwed to the support 32 and therefore move along with the support 32 when the lifting device 30 is active. Alternatively, the linear actuators 28 can also be attached to the support 32 in a magnetic manner and/or by means of a vacuum.

The linear actuators 28 are therefore not integrated into the substrate receiving device 18, but are firmly connected to the support 32. A simple design and a high degree of design freedom of the substrate receiving device 18 are thus achieved.

Furthermore, the positioning device 10 has a control unit 34 which is configured and set up to specify travel paths of the linear actuators 28 as a function of the measured ram pressures. As a result, the distance of the substrate receiving device 18 and thus also of the substrate 12 from the mask 16 can be set very precisely.

Two linear guides 36 are also provided to avoid tilting or twisting movements of the substrate receiving device 18 or the support 32 during movements of the substrate receiving device 18 and/or the support 32 towards or away from the mask 16. The linear guides 36 are configured as column guides and are arranged on opposite circumferential sides of the substrate receiving device 18 or the support 32. They only permit movements of the substrate receiving device 18 or the support 32 perpendicular to the mask 16.

Optionally, windows or openings 38 can also be provided in the support 32 and/or the substrate receiving device 18, through which substrate markings on the underside of the substrate can be detected for alignment purposes (so-called back-side alignment).

The positioning device 10 is intended to perform a method of aligning a substrate 12 relative to the substantially flat surface 14 of the mask 16.

One example embodiment of this method is briefly explained below.

In an upstream first step of the method, the pressure measuring devices 24 are calibrated. For this purpose, the ram pressures of the ram pressure nozzles 22 are respectively sensed at various known distances of the substrate receiving device 18 or the ram pressure nozzles 22 from the substantially flat surface 14. The correlation found is stored. For example, individual configuration files can thus be created for different substrate receiving devices 18.

The calibration can also be repeated for different prevailing air pressures or reference ram pressure values detected with the reference ram pressure nozzle 26, so that an air pressure-dependent correlation of the ram pressures of the respective ram pressure nozzles 22 with the distance thereof from the substantially flat surface 14 can be detected and stored.

In this context, it is also possible to specify one or more ram pressure switching points or that these are already specified. In the example embodiment, all ram pressure nozzles 22 have the same ram pressure switching point, which is defined by a common ram pressure value.

Alternatively, different ram pressure switching points can however also be provided for the different ram pressure nozzles 22. For example, the ram pressure switching points of the individual ram pressure nozzles 22 can be defined by a common distance value from the substantially flat surface 14, which is between 1 μm and 1000 μm, preferably 100 μm to 200 μm. Depending on the calibration, different ram pressures of the individual ram pressure nozzles 22 may prevail at the common distance value (i.e. if all ram pressure nozzles 22 have the same distance from the substantially flat surface 14).

Of course, the ram pressure switching point(s) can also be dependent on the air pressure and/or the reference ram pressure.

In principle, the calibration step does not have to be carried out again for each alignment of a substrate 12 by means of the positioning device 10. It may be sufficient if this step is carried out, for example, after the positioning device 10 has been arranged or set up or after changes have been made to the positioning device 10.

In a second step of the method, a dimension of the substrate 12 is determined by means of a measuring device, in particular a substrate thickness and a wedge shape of the substrate 12.

The positioning device 10 is then loaded with the substrate 12.

In a third step of the method, the lifting device 30 moves the support 32 and thus also the substrate receiving device 18 with the substrate 12 towards the substantially flat surface 14 of the mask 16. The ram pressures of the ram pressure nozzles 22 are sensed and transmitted to the control unit 34.

As the distance from the mask 16 decreases, the ram pressures of the ram pressure nozzles 22 increase. This increase is detected by the pressure measuring devices 24.

In one variant embodiment of the method, a signal is output in a fourth step when the ram pressure switching point of at least one of the ram pressure nozzles 22 is reached. The signal stops the further approach of the support 32 to the mask 16 by means of the lifting device 30.

At the same time, the signal initiates a fifth process step in which the control unit 34 determines local distance values of the substrate receiving device 18 from the substantially flat surface 14 at the positions of the ram pressure nozzles 22 on the basis of the ram pressures of the ram pressure nozzles 22 and the calibration data.

In a subsequent sixth process step, the control unit 34 then determines travel paths by which the linear actuators 28 are to be moved to achieve a parallel alignment of the substrate 12 to the substantially flat surface 14 of the mask 16 on the basis of the local distance values and the substrate dimension.

In a seventh process step, the linear actuators 28 move the substrate receiving device 18 and thus also the substrate 12 by the previously determined travel paths in the direction of the substantially flat surface 14 of the mask 16.

A parallel alignment of the substrate 12 to the mask 16 is thus achieved.

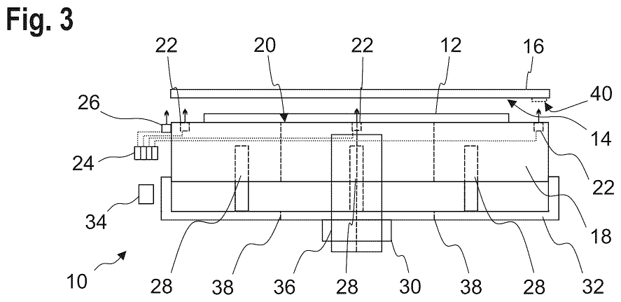

FIG. 3 shows a second embodiment of a positioning device 10 according to the invention. It corresponds in several essential aspects to the first embodiment shown in FIGS. 1 and 2, so that only the differences are discussed below. The same reference numerals are used for identical or functionally identical features.

In the second embodiment, the support 32 and the substrate receiving device 18 form a closed component, for example a chuck. The linear actuators 28 are received in the closed component. As a result, an extremely compact and space-saving design can be achieved.

In the second embodiment, the substrate receiving device 18 is also adapted to be adjusted relative to the support 32 by the linear actuators 28, so that a method according to the invention of aligning a substrate 12 relative to a substantially flat surface 14 can be using the positioning device 10, in particular the embodiment of such a method explained above.

Of course, this is not to be understood in a restrictive manner. Other process sequences are also conceivable.

For example, it may be provided that during the movement of the substrate receiving surface 20 towards the substantially flat surface 14, the ram pressure switching points of all ram pressure nozzles 22 are reached, in particular wherein the ram pressure switching points of at least two ram pressure nozzles 22 do not switch simultaneously, but at different points in time, if the substrate receiving surface 20 is not aligned parallel to the substantially flat surface 14.

By means of the ram pressure switching points and the local distance values correlating therewith, the speed of movement of the lifting device 30 in the direction of the substantially flat surface 14, which is in particular constant until all ram pressure switching points are reached, the elapsed time between reaching the respective ram pressure switching point of a ram pressure nozzle 22 and the end of the movement of the substrate receiving surface 20 and/or the position coordinates of the ram pressure nozzles 22, it is possible to determine the final, i.e. the local distance values present at the end of the movement of the substrate receiving surface 20, and consequently the travel path of at least one linear actuator 28 required for aligning the substrate 12.

Preferably, when determining the travel path of at least one linear actuator 28, the ram pressure nozzle 22 can be used as a static reference point which is furthest away from the substantially flat surface 14 at the time of the end of the movement of the substrate receiving surface 20, i.e. the ram pressure switching point of which was reached last and/or is still reached at the time of the end of the movement of the substrate receiving surface 20.

As a result of such a determination of the travel path of at least one linear actuator 28, at least one linear actuator 28 is moved such that all ram pressure nozzles 22 which are not used as a static reference point are moved to a position at which they have their respective ram pressure switching point.

If, at the time of the end of the movement of the substrate receiving surface 20, the ram pressure nozzle 22 used as a static reference point had still reached its ram pressure switching point, all ram pressure nozzles 22 have reached their ram pressure switching point after the movement of the linear actuators 28, as explained in the foregoing, so that the substrate receiving surface 20 is now aligned parallel to the substantially flat surface 14.

If, at the time of the end of the movement of the substrate receiving surface 20, the ram pressure nozzle 22 used as a static reference point had not (or no longer) reached its ram pressure switching point, at least the ram pressure nozzle 22 used as a static reference point must be moved to a position at which it has its respective ram pressure switching point, for example via the lifting device 30 or at least one linear actuator 28, after or before the parallel alignment of the substrate receiving surface 20 to the substantially flat surface 14.

In both cases, after the alignment of the substrate receiving surface 20 parallel to the substantially flat surface 14, the substrate receiving surface 20 need only be moved a small distance, or even no distance, so that all ram pressure nozzles 22 reach their ram pressure switching point and thus the desired distance is provided between the substrate receiving surface 20 and the substantially flat surface 14.

Alternatively, any one of the ram pressure nozzles 22 may be used as a static reference point for aligning the substrate receiving surface 20 parallel to the substantially flat surface 14 by means of the linear actuators 28.

If necessary, a repeated “approach” of the substrate receiving surface 20 to the substantially flat surface 14 may be performed to achieve the desired distance between the substrate receiving surface 20 and the substantially flat surface 14.

In an optional further step, it may be provided that after the alignment of the substrate receiving surface 20 parallel to the substantially flat surface 14, the substrate receiving surface 20 is again moved away from the substantially flat surface 14 and back towards the substantially flat surface 14 until a switching point of at least one ram pressure nozzle 22 is again reached. In this way, it is possible to check whether the ram pressure switching points of all ram pressure nozzles 22 are reached simultaneously within a predetermined or defined tolerance range and thus whether the desired parallelism of the substrate receiving surface 20 and the substantially flat surface 14 is provided.

If the times of the ram pressure switching points are outside the tolerance range, individual steps or all previous steps may be repeated to achieve the desired parallelism of the substrate receiving surface 20 and the substantially flat surface 14.

Optionally, the fact applies to the described embodiments of the positioning devices 10 and the method embodiments, that the movement of the substrate receiving device 18 using the linear actuators 28 also produces a contact of the substrate 12 with the mask 16, so that further processing steps of the substrate 12, for example an exposure through the mask 16, can be carried out directly following the method according to the invention.

1. A positioning device for aligning a substrate relative to a substantially flat surface, comprising:
a substrate receiving device configured for receiving the substrate;
at least three ram pressure nozzles arranged on or around the substrate receiving device, each of the ram pressure nozzles being oriented towards the substantially flat surface and being connected to a pressure measuring device for sensing the respective ram pressure thereof;
at least two linear actuators connected to the substrate receiving device and each configured to move the substrate receiving device relative to the substantially flat surface; and
a control unit which is configured and set up to preset travel paths of the linear actuators as a function of the measured ram pressures.

2. The positioning device of claim 1, further comprising a support, wherein the linear actuators are arranged evenly spaced apart from each other on the support, in particular wherein the support is part of a lifting device.

3. The positioning device of claim 2, wherein the linear actuators are fixed onto the support mechanically, magnetically, by an adhesive and/or by a vacuum.

4. The positioning device of claim 2, wherein the support and the substrate receiving device form a closed component, for example a chuck, in which at least the linear actuators are received, wherein the substrate receiving device is configured to be adjusted relative to the support by the linear actuators.

5. The positioning device of claim 1, wherein the ram pressure nozzles are arranged outside a substrate receiving surface of the substrate receiving device.

6. The positioning device of claim 1, comprising at least one linear guide which is configured to linearly guide the substrate receiving device during movements towards or away from the substantially flat surface.

7. The positioning device of claim 1, comprising at least one reference ram pressure nozzle the ram pressure of which is substantially independent of a relative position of the substrate receiving device to the substantially flat surface and/or is dependent on an ambient pressure.

8. A method of aligning a substrate relative to a substantially flat surface using a positioning device according to claim 1, comprising the steps of:
moving the substrate receiving device towards the substantially flat surface, ram pressures of the ram pressure nozzles being sensed during moving;
determining local distance values of the substrate receiving device from the substantially flat surface on the basis of the ram pressures;
determining a travel path of at least one of the linear actuators based on the local distance values; and
moving the at least one linear actuator by the travel path.

9. The method of claim 8, comprising the further step of:
determining a substrate dimension, in particular a substrate thickness and/or a wedge shape of the substrate, wherein the travel path is determined based on the local distance values and the substrate dimension.

10. The method of claim 8, comprising the further step of:
calibrating the pressure measuring device by detecting and storing a correlation of a ram pressure of at least one of the ram pressure nozzles and a distance of the at least one ram pressure nozzle from the substantially flat surface.

11. The method of claim 8, wherein at least one ram pressure switching point is predetermined, wherein in the event that the ram pressure of at least one of the ram pressure nozzles reaches the ram pressure switching point, the pressure measuring device outputs a signal, wherein the determination of the local distance values and/or the determination of the travel path is initiated by the signal.
